(19) United States
(12) Patent Application Publication
(10) Pub. No.: US 2015/0128859 A1
(43) Pub. Date: May 14, 2015

(54) DEPOSITION SYSTEM

(71) Applicant: MINGDAO UNIVERSITY, Changhua County (TW)

(72) Inventors: Chi-Lung CHANG, Taichung City (TW); Wan-Yu WU, Taipei City (TW); Pin-Hung CHEN, Kaohsiung City (TW); Wei-Chih CHEN, Yunlin County (TW); Da-Yung WANG, Taichung City (TW)

(73) Assignee: MINGDAO UNIVERSITY, Changhua County (TW)

(21) Appl. No.: 14/261,417

(22) Filed: Apr. 24, 2014

(30) Foreign Application Priority Data
Nov. 13, 2013 (TW) 102141280

(51) Int. Cl. H01J 37/32

(52) U.S. Cl. CPC H01J 37/32972; H01J 37/32669; H01J 37/32577; H01J 37/32981
USPC 118/712

(57) ABSTRACT

A deposition system includes a chamber, an electrical power module, a first detection module and a second detection module. The chamber includes a target, a substrate, and a plasma. The substrate is spaced apart with the target and corresponded to the target. The plasma is generated between the target and the substrate. The target, the substrate and the plasma are in an interior of the chamber. The electrical power module is electrically connected with the target so as to generate a potential difference between the target and the substrate. The first detection module is connected with the interior of the chamber for detecting a composition of the plasma so as to generate a first detection result. The second detection module is connected with the first detection module, and includes an avalanche photodiode detector for analyzing the first detection result so as to generate a second detection result.

### RELATED APPLICATIONS

This application claims priority to Taiwan Application Serial Number 102141280, filed Nov. 13, 2013, which is herein incorporated by reference.

### BACKGROUND

1. Technical Field

The present disclosure relates to a deposition system. More particularly, the present disclosure relates to a deposition system for detecting and analyzing a composition of a plasma.

2. Description of Related Art

Plasma is widely used in surface treatment techniques, including physical vapor deposition techniques, chemical vapor deposition techniques and etching techniques. In a surface treatment process, the quality of the surface treatment is closely related to a composition of the plasma.

For an example, in a sputtering process of physical vapor deposition, the ions of the plasma bombard the target, so that the surface atoms of the target are dislodged from the target surface and are deposited on a substrate. After adhesion, adsorption, surface migration and nucleation, a film is formed on the substrate. A number of researches have indicated that characteristics of the film depend on an ionization degree and a density of the plasma. When the ionization degree and the density of the plasma are increased, the characteristics of the film are enhanced, such as the density, the adhesion, the wear resistance, the corrosion resistance and the mechanical properties of the film. Therefore, if the change of the composition of the plasma can be detected instantly during the sputtering process, the reaction mechanisms of the sputtering process can be well understood. As a result, the sputtering process can be optimized so as to improve the characteristics of the film.

However, a time sensitivity of a conventional device for detecting the plasma is only up to the order of second. The conventional device fails to provide a more fine and correct detection result, so that the optimization degree of the sputtering process is limited. Therefore, a device for detecting the plasma with a better sensitivity for providing a more fine and correct detection result is in demand.

### SUMMARY

According to one aspect of the present disclosure, a deposition system includes a chamber, an electrical power module, a first detection module and a second detection module. The chamber includes a target, a substrate, and a plasma. The substrate is spaced apart with the target and corresponded to the target. The plasma is generated between the target and the substrate. The target, the substrate and the plasma are in an interior of the chamber. The electrical power module is electrically connected with the target so as to generate a potential difference between the target and the substrate. The first detection module is connected with the interior of the chamber for detecting a composition of the plasma so as to generate a first detection result. The second detection module is connected with the first detection module, and the second detection module includes an avalanche photodiode detector for analyzing the first detection result so as to generate a second detection result.

According to another aspect of the present disclosure a deposition system includes a chamber, an electrical power module, a gas providing module, a first detection module, a second detection module and a feedback control module. The chamber includes a target, a substrate, and a plasma. The substrate is spaced apart with the target and corresponded to the target. The plasma is generated between the target and the substrate. The target, the substrate and the plasma are in an interior of the chamber. The electrical power module is electrically connected with the target so as to generate a potential difference between the target and the substrate. The gas providing module is connected with the interior of the chamber for providing a gas into the interior the chamber. The first detection module is connected with the interior of the chamber for detecting a composition of the plasma so as to generate a first detection result. The second detection module is connected with the first detection module, and the second detection module includes an avalanche photodiode detector for analyzing the first detection result so as to generate a second detection result. The feedback control module is connected with the first detection module, and the feedback control module is for calculating the first detection result so as to generate a signal to control the gas providing module.

### BRIEF DESCRIPTION OF THE DRAWINGS

The disclosure can be more fully understood by reading the following detailed description of the embodiment, with reference made to the accompanying drawings as follows:

FIG. 1 is a schematic view of a deposition system according to one embodiment of the present disclosure;

FIG. 2 is a schematic view of a deposition system according to another embodiment of the present disclosure;

FIG. 3 shows a first detection result generated by a first detection module according to one embodiment of the present disclosure;

FIG. 4 shows a second detection result generated by a second detection module according to one embodiment of the present disclosure; and

FIG. 5 shows a corrected result obtained by a feedback control module according to one embodiment of this disclosure.

### DETAILED DESCRIPTION

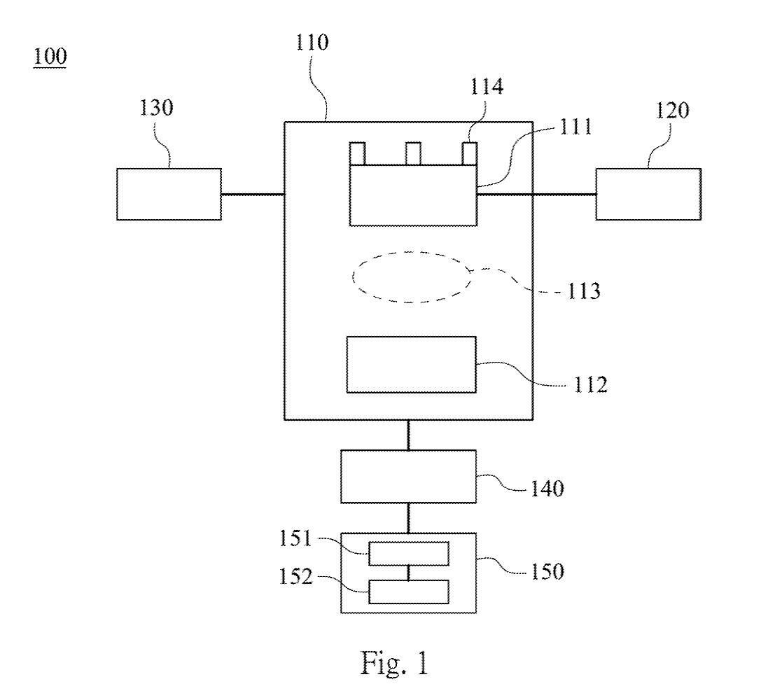

FIG. 1 is a schematic view of a deposition system 100 according to one embodiment of the present disclosure. In FIG. 1, the deposition system 100 includes a chamber 110, an electrical power module 120, a gas providing module 130, a first detection module 140 and a second detection module 150, The gas providing module 130 is connected with an interior of the chamber 110. The first detection module 140 is connected with the interior of the chamber 110. The second detection module 150 is connected with the first detection module 140. In the embodiment, the deposition system 100 is applied to a sputtering process of physical vapor deposition.

The chamber 110 includes a target 111, a plurality of magnetic elements 114, a substrate 112 and a plasma 113 in the interior thereof. The substrate 112 is spaced apart with the target 111 and corresponded to the target 111 The plasma 113 is generated between the target 111 and the substrate 112. A distance between the magnetic elements 114 and the target 111 is shorter than a distance between the magnetic elements 114 and the substrate 112. In the embodiment, the magnetic elements 114 are disposed on a surface of the target 111, and the surface of the target 111 faces away from the substrate 112. A movement path of electrons of the plasma 113 is influenced by the magnetic elements 114, so that collisions between the electrons and gas molecules of the plasma 113 are increased. As a result, an ionization degree of the plasma 113 is enhanced, and a deposition rate and a film quality are enhanced thereby.

The electrical power module 120 is electrically connected with the target 111 so as to generate a potential difference between the target 111 and the substrate 112, whereby the plasma 113 is generated in the chamber 110. in the embodiment, the electrical power module 120 is connected with the target 111 for providing the target 111 an electrical pulse (not illustrated in FIG. 1). A power density of the electrical pulse can be 2 kWcm⁻² to 300 kWcm⁻², an instantaneous power of the electrical pulse can be 2 kW to 600 kW, and a pulse repetition frequency of the electrical pulse can be 100 Hz to 50 kHz. Therefore, a density and the ionization degree of the plasma 113 can be further enhanced, and a rate of atoms dislodged from a surface of the target 111 can be enhanced. As a result, a density of a film deposited on the substrate 112, an adhesion between the film and the substrate 112, mechanical properties of the film, and corrosion resistance of the film are enhanced.

The gas providing module 130 is connected with the interior of the chamber 110, and the gas providing module 130 is for providing at least one kind of gas into the interior the chamber 110. The gas provided by the gas providing module 130 can be but not limited to argon, nitrogen or oxygen. The gas providing module 130 can provide single kind of gas or more than one kind of gas. When the gas providing module 130 provides more than one kind of gas, an amount ratio of different kinds of gases can be adjusted, too. Furthermore, the gas provided by the gas providing module 130 can be a reactive gas or a neutral gas. The aforementioned “reactive gas” refers to a gas which reacts with the atoms of the target 111, i.e., atoms of the gas combine with the atoms of the target 111 so as to generate a compound deposited on the substrate 112. In other words, the gas is one of the sources of the film. The aforementioned neutral gas refers to a gas which does not react with the atoms of the target 111, i.e. atoms of the gas does not combine with the atoms of the target 111 to form a compound deposited on the substrate 112. A flow rate of the gas determines a gas pressure of the chamber 110. Therefore, the density of the plasma 113 and the collisions occurred in the plasma 113 are dependent on the flow rate of the gas in despite of what kind of the gas is (the reactive gas or the neutral gas). Accordingly, the quality of the film is dependent on the flow rate of the gas.

The first detection module 140 is connected with the interior of the chamber 110, and is for detecting a composition of the plasma 113. Specifically, a collimator (not illustrated in FIG. 1) is disposed in the interior of the chamber 110 where the plasma 113 is generated. The collimator is for collecting signals of the plasma 113. The signals of the plasma 113 are relevant to the composition of the plasma 113, and the signals of the plasma 113 are delivered to the first detection module 140 via an optical fiber (not illustrated in FIG. 1). The first detection module 140 detects the composition of the plasma 113 and generates a first detection result. The second detection module 150 includes an avalanche photodiode detector 151 and an oscilloscope 152. The avalanche photodiode detector 151 can analyze the first detection result generated by the first detection module 140 and can generate a second detection result. The second detection result is displayed via the oscilloscope 152.

In the embodiment, an optical emission spectrometry (OES) is adopted as the first detection module 140. A wavelength range detected by the OES is 200 nm to 1100 nm, and the OES can instantly detect a concentration of the plasma 113 without delay.

The second detection result generated by the second detection module 150 is more fine and accurate than the first detection result generated by the first detection module 140. For an example, when the OES is adopted as the first detection module 140, the time sensitivity of the OES is up to the order of second (s), and the time sensitivity of the avalanche photodiode detector 151 is up to the order of microsecond (μs). Therefore, when an operator would like to deeply analyze the first detection result generated by the first detection module 140, or when the first detection result generated by the first detection module 140 shows an abnormality, the operator can monitor the change of the composition of the plasma 113 in an extremely short time during a sputtering process via the second detection result generated by the second detection module 150.

When the electrical power module 120 provides the target 111 the electrical pulse, the composition of the plasma 113 is changed at the instant which the electrical pulse is generated. The action time of the electrical pulse is much shorter than a second. Therefore, the first detection module 140 is fail to provide the composition of the plasma 113 at the instant which the electrical pulse is generated due to the limit of the time sensitivity thereof. The time sensitivity of the second detection module 150 is up to the order of microsecond, which is capable for providing the composition of the plasma 113 at the instant which the electrical pulse is generated. Therefore, the operator can monitor the change of the composition of the plasma 113 via the first detection module 140 and the second detection module 150. When the composition of the plasma 113 is undesirable, the operator can adjust the composition of the plasma 113 by changing the composition the gas or the flow rate of the gas provided by the gas providing module 130, or controlling the power or the action time of the electrical pulse provided by the electrical power module 120.

In the embodiment, the deposition system 100 is applied to the sputtering process of physical vapor deposition, which is only for exampling. The deposition system 100 can be applied to other sputtering processes. As long as the plasma 113 is generated in the chamber 110, the deposition system 100 can be applied to detect and analyze the composition of the plasma 113.

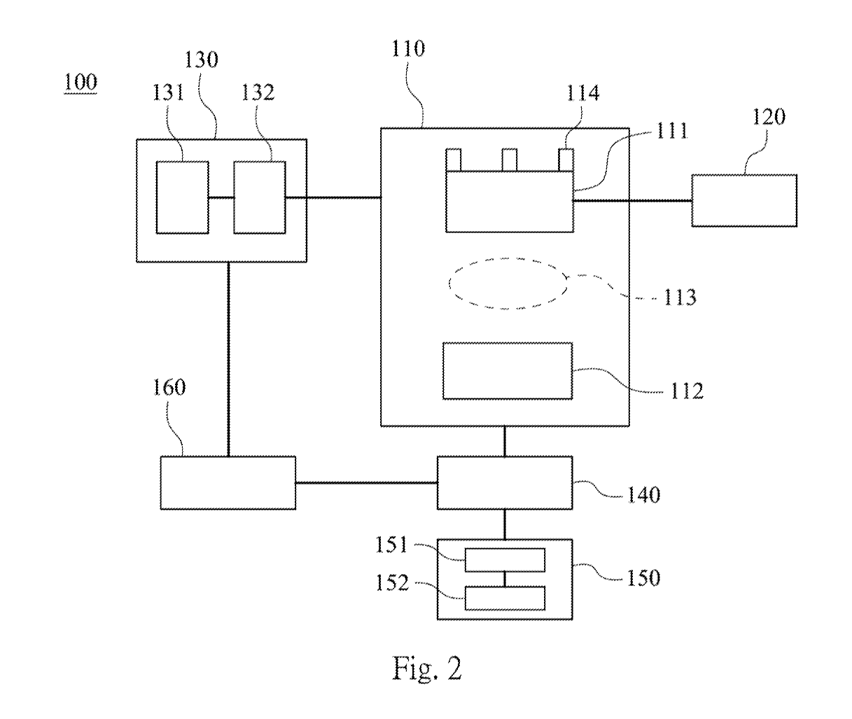

FIG. 2 is a schematic view of a deposition system 100 according to another embodiment of the present disclosure. In FIG. 2, the deposition system 100 includes a chamber 110, an electrical power module 120, a gas providing module 130, a first detection module 140, a second detection module 150 and a feedback control module 160. The gas providing module 130 is connected with an interior of the chamber 110. The first detection module 140 is connected with the interior of the chamber 110. The second detection module 150 is connected with the first detection module 140. The feedback control module 160 is connected with the first detection module 140 and the gas providing module 130.

The gas providing module 130 includes at least one gas source 131 and at least one flow control valve 132. The gas source 131 includes a gas therein. The flow control valve 132 is for controlling a flow rate of the gas of the gas source 131 into the chamber 110. In one embodiment, a piezo valve is adopted as the flow control valve 132, and a precision of the piezo valve is −0.1% to +0.1%.

The feedback control module 160 receives and calculates the first detection result generated by the first detection module 140, then generates a signal to control the gas providing module 130. For an example, the signal can determine a composition of the gas or the flow rate of the gas provided by the gas providing module 130 into the chamber 110. In one embodiment, a proportional integral derivative control is adopted as the feedback control module 160, which can calculate the first detection result generated by the first detection module 140 so as to obtain a measured value. A deviation value is obtained by subtracting the measured value from the expected value. Then a corrected value for correcting the deposition system 100 is calculated according to the deviation value, and the corrected value is adopted as the signal for controlling the gas providing module 130. Therefore the sputtering process can be corrected so as to approach to the expected value, and a target poisoning can be avoided. As a result, the process can be optimized.

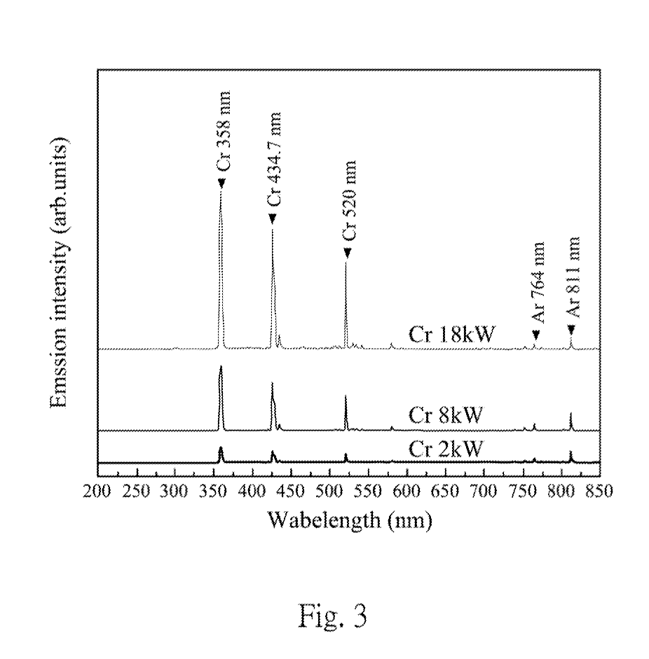

FIG. 3 shows a first detection result generated by a first detection module according to one embodiment of the present disclosure. In the embodiment, a target is chromium. Argon is provided by a gas providing module. Electrical pulses having an instantaneous power of 2 kW, 8 kW and 18 kW respectively are provided by an electrical power module. An OES is adopted as the first detection module for detecting a composition of a plasma. In FIG. 3, when the instantaneous power of the electrical pulse is increased, the emission intensity is increased, too. Furthermore, an operator can monitor the composition of the plasma in real time. The composition of the plasma includes the species of particles of the plasma or the amount of the particles of the plasma.

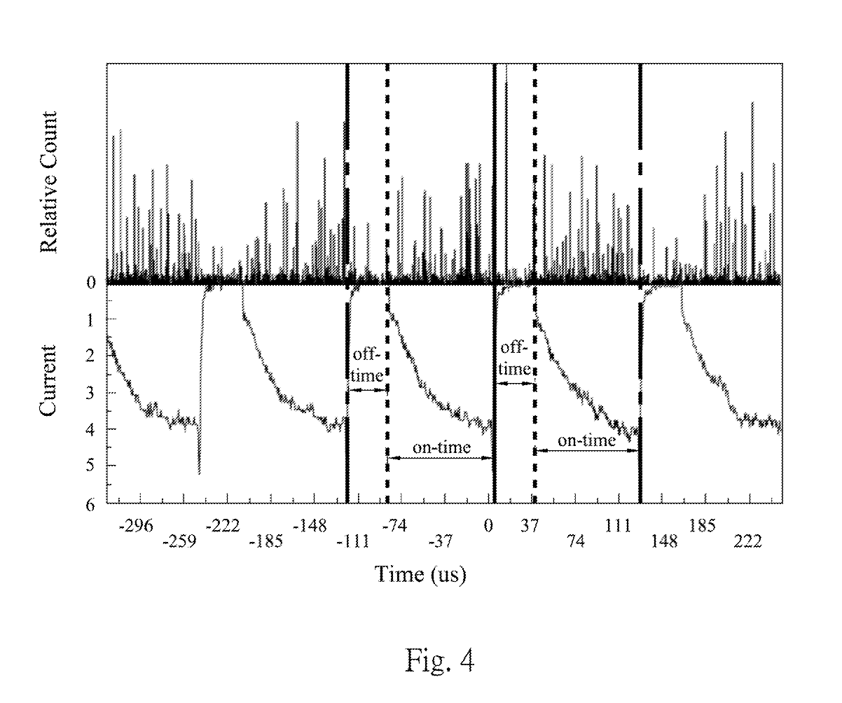

FIG. 4 shows a second detection result generated by a second detection module according to one embodiment of the present disclosure. The upper half of FIG. 4 shows the relationship between the relative count of a plasma and time. The lower half of FIG. 4 shows the relationship between the current of the plasma and time. In FIG. 4, the time sensitivity of the second detection module is up to the order of microsecond. Therefore, the operator can monitor the change of the composition of the plasma during the sputtering process more finely and correctly. Especially, when electrical pulses are provided by an electrical power module, the second detection module can provide the desired time sensitivity.

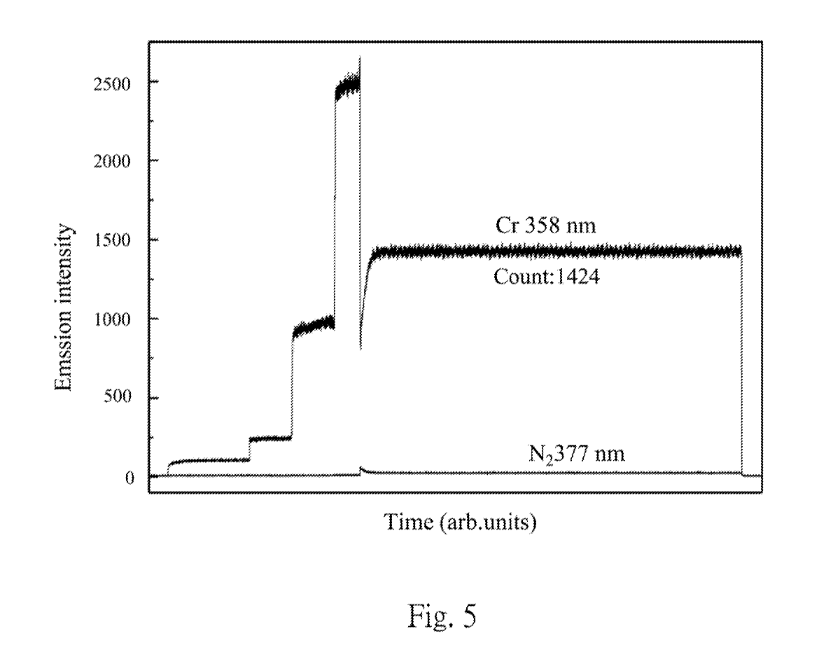

FIG. 5 shows a corrected result obtained by a feedback control module according to one embodiment of this disclosure. In the embodiment, a proportional integral derivative control is adopted as the feedback control module. A target is chromium. An expected value of an emission intensity of chromium is 1500. The feedback control module receives and calculates a first detection result generated by a first detection module. Then a signal for controlling a gas providing module is generated by the feedback control module, so that the emission intensity of chromium gradually approaches to the expected value and then maintains at the expected value. Therefore, the sputtering process can approach to the expected value automatically. As a result, the sputtering process can be optimized, and the manpower can be reduced.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A deposition system, comprising:
a chamber, comprising:
a target;
a substrate spaced apart with the target and corresponded to the target; and
a plasma generated between the target and the substrate;
wherein the target, the substrate and the plasma are in an interior of the chamber;
an electrical power module electrically connected with the target so as to generate a potential difference between the target and the substrate;
a first detection module connected with the interior of the chamber for detecting a composition of the plasma so as to generate a first detection result; and
a second detection module connected with the first detection module, wherein the second detection module comprises an avalanche photodiode detector for analyzing the first detection result so as to generate a second detection result.

2. The deposition system of claim 1, wherein the electrical power module is connected with the target for providing the target an electrical pulse.

3. The deposition system of claim 2, wherein a power density of the electrical pulse is 2 kWcm⁻² to 300 kWcm⁻², an instantaneous power of the electrical pulse is 2 kW to 600 kW, and a pulse repetition frequency of the electrical pulse is 100 Hz to 50 kHz.

4. The deposition system of claim 1, wherein the chamber further comprises a magnetic element, a distance between the magnetic element and the target is shorter than a distance between the magnetic element and the substrate, and the magnetic element is for enhancing an ionization degree of the plasma.

5. The deposition system of claim 1, further comprising a gas providing module connected with the interior of the chamber, wherein the gas providing module is for providing a gas into the interior the chamber.

6. A deposition system, comprising:
a chamber, comprising:
a target;
a substrate spaced apart with the target and corresponded to the target; and
a plasma generated between the target and the substrate:
wherein the target, the substrate and the plasma are in an interior of the chamber;
an electrical power module electrically connected with the target so as to generate a potential difference between the target and the substrate;
a gas providing module connected with the interior of the chamber for providing a gas into the interior the chamber;
a first detection module connected with the interior of the chamber for detecting a composition of the plasma so as to generate a first detection result;
a second detection module connected with the first detection module, wherein the second detection module comprises an avalanche photodiode detector for analyzing the first detection result so as to generate a second detection result; and
a feedback control module connected with the first detection module, wherein the feedback control module is for calculating the first detection result so as to generate a signal to control the gas providing module.

7. The deposition system of claim 6, wherein the signal is for determining a composition of the gas or a flow rate of the gas.

8. The deposition system of claim 6, wherein the electrical power module is connected with the target for providing the target an electrical pulse.

9. The deposition system of claim 8, wherein a power density of the electrical pulse is 2 kWcm⁻² to 300 kWcm⁻², an instantaneous power of the electrical pulse is 2 kW to 600 kW, and a pulse repetition frequency of the electrical pulse is 100 Hz to 50 kHz.

10. The deposition system of claim 6, wherein the chamber further comprises a magnetic element, a distance between the magnetic element and the target is shorter than a distance between the magnetic element and the substrate, and the magnetic element is for enhancing an ionization degree of the plasma.
